(19) United States
(12) Patent Application Publication
(10) Pub. No.: US 2026/0276677 A1
(43) Pub. Date: Sep. 17, 2026

(54) CIRCUIT CARRIER, MEASUREMENT APPLICATION DEVICE AND METHOD

(71) Applicant: ROHDE & SCHWARZ GMBH & CO. KG, München (DE)

(72) Inventors: Maximilian FRIESINGER, München (DE); Nico RIEDMANN, München (DE); Roman SAMMER, Mariaposching (DE); Iliya ILIEV, München (DE)

(73) Assignee: ROHDE & SCHWARZ GMBH & CO. KG, München (DE)

(21) Appl. No.: 19/552,223

(22) Filed: Feb. 27, 2026

(30) Foreign Application Priority Data
Mar. 14, 2025 (DE) 102025109903.0

(51) Int. Cl. G01R 3/00; G01R 23/16

(52) U.S. Cl. CPC G01R 3/00; G01R 23/16

(57) ABSTRACT

The present disclosure shows a circuit carrier, comprising a carrier substrate comprising one or more inner layers, a carrier substrate having one or more first outer layers and one or more second outer layers, wherein the first outer layers and the second outer layers are arranged on opposite sides of the inner layers, and an internal recess, which extends from at least one of the first outer layers to at least one of the second outer layers through the inner layers, wherein the circuit carrier further comprises a heat dissipation element, which is arranged in the recess and has a first side facing the first outer layers, and a second side facing the second outer layers. Furthermore, the present disclosure shows a corresponding measurement application device and a corresponding method.

### CROSS-REFERENCE TO RELATED APPLICATIONS

This application claims foreign priority to German Application No. DE 102025109903.0 filed Mar. 14, 2025, the disclosure of which is hereby incorporated in its entirety by reference herein.

### TECHNICAL FIELD

The present disclosure relates to a circuit carrier, a measurement application device and a corresponding method.

### BACKGROUND

The present disclosure will be described hereinafter mainly in connection with measurement application devices, such as network analyzers and signal generators. It is understood that the disclosure is not limited to such devices and can be used in all systems or applications in which waste heat from electrical components on a circuit board must be dissipated.

In modern measurement application devices, such as network analyzers and signal generators, powerful semiconductors, e.g., amplifiers, are required in order to generate or measure the signals necessary for the respective measurement task.

Depending on their power, such semiconductors generate corresponding waste heat, which must be dissipated from the semiconductors.

### SUMMARY

An object of the disclosure is therefore to improve heat dissipation for electrical components.

The object is achieved by the subject matter of the independent claims.

Disclosed is:
A circuit carrier, comprising a carrier substrate comprising one or more inner layers, one or more first outer layers, also referred to herein only as first layers, and one or more second outer layers, also referred to herein only as second layers, wherein the first outer layers and the second outer layers are arranged on opposite sides of the inner layers, and comprising an internal recess, which extends from at least one of the first outer layers to at least one of the second outer layers through the inner layers, wherein the circuit carrier further comprises a heat dissipation element, which is arranged in the recess and has a first side facing the first outer layers, and a second side facing the second outer layers.

Further disclosed is:
A measurement application device, comprising at least one circuit carrier according to the present disclosure, wherein at least one electrical component, in particular an amplifier, is arranged on the at least one circuit carrier on the outermost of the first outer layers above the heat dissipation element.

Further disclosed is:
A method for producing a circuit carrier according to the present disclosure, wherein the method comprises: forming a recess in one or more inner layers of a carrier substrate, inserting a heat dissipation element into the recess, arranging one or more first outer layers on a first side of the inner layers, and arranging one or more second outer layers on a second side of the inner layers, wherein the heat dissipation element has a first side facing the first outer layers, and a second side facing the second outer layers.

The insight underlying the present disclosure is that the use of integrated power semiconductors leads to increased local heat generation. For example, amplifiers are frequently used in modern measurement application devices, such as oscilloscopes, network analyzers, or signal generators. Such amplifiers, particularly those with high output powers, generate corresponding amounts of waste heat that must be dissipated.

In order to be able to increase the output power of amplifiers, which are available as integrated components, the heat dissipation must be correspondingly improved.

The idea underlying the present disclosure is therefore to take this insight into account and to provide a circuit carrier which enables increased heat dissipation for components mounted on its surface.

For this purpose, the circuit carrier comprises a carrier substrate which has one or more inner layers as well as first and second outer layers. A recess is provided in the inner layers, in which a heat dissipation element is arranged.

The carrier substrate with the inner layers and first and second outer layers can also be regarded as a circuit board, printed circuit board or component carrier. The carrier substrate can be produced, for example, based on manufacturing processes for multilayer printed circuit boards.

The inner layers can, for example, have conductive and non-conductive layers, which both ensure the stability of the carrier substrate and also enable internal electrical connections in the carrier substrate. The first and second outer layers serve in particular for mounting or fixing electrical components, such as integrated circuits. Although usable with any type of component, the present disclosure will be described particularly in connection with surface-mounted components, also called surface-mount devices or SMD components.

For producing the circuit carrier, a recess can be formed in the one or more inner layers of the carrier substrate, into which the heat dissipation element is inserted. The first and second outer layers can be applied to the inner layers after the insertion of the heat dissipation element. However, either the first or the second outer layers can also be applied to the inner layers before the insertion of the heat dissipation element. The heat dissipation element has a first side facing the first outer layers, and a second side facing the second outer layers.

The recess can in particular extend through all inner layers. The recess can be introduced into the inner layers, for example, by milling, cutting, in particular laser cutting or water jet cutting. This can be done for individual inner layers before they are pressed or glued together. Alternatively, the inner layers can first be pressed or glued together and the recess introduced afterwards.

The heat dissipation element can be formed, for example, in one piece. Such heat dissipation elements can be produced, for example, by milling, turning or 3D printing. The heat dissipation element can be inserted into the recess in the already pressed or glued inner layers. Alternatively, individual, not yet pressed or glued inner layers, which already have the cutout for the recess, can be placed onto the heat dissipation element one after another. This stack can subsequently be pressed or glued.

In further manufacturing steps, for example, the outer surface of the outermost inner layer facing the first outer layers, or the outermost inner layer facing the second outer layers, or both surfaces, can be smoothed, e.g., surface milled. Unevenness in the inner layers or between the inner layers and the first or second outer layers can also be compensated for by a corresponding prepreg in the first or second outer layers.

During operation of an electrical circuit constructed on the basis of the circuit carrier, the heat dissipation element serves to dissipate heat from a component that is mounted on the first outer layers.

Modern amplifiers are available as integrated circuits. Such components can be mounted as SMD components, e.g., in a so-called RQFN housing or package, onto the outer surface of the carrier substrate on the outermost of the first outer layers. The component can be placed such that the heat dissipation element lies directly under the corresponding component. Heat generated in the component can consequently be absorbed by the underlying heat dissipation element and transported away from the component through the inner layers by the latter.

Such components can in particular have a so-called “exposed ground pad”. An “exposed ground pad” is an electrical ground contact of the respective component, which is led outwards on its underside, in particular formed over a large area. Such a large-area contact supports heat conduction from the interior of the component to the outside. The component can be placed such that the “exposed ground pad” lies above the heat dissipation element. It is understood that contacts other than a ground contact can also be led out of the component as large-area contacts. Such contacts can carry, for example, supply voltages or electrical signals.

Effective cooling of the component can thus be ensured. Consequently, the service life of the respective component can be increased and simultaneously its output power can be increased.

The circuit carrier according to the present disclosure can be used, for example, in corresponding measurement application devices, but is not limited thereto. A corresponding circuit carrier can also be used, for example, in RF amplifier circuits.

A measurement application device according to the present disclosure can comprise any device that is used in a measurement application for acquiring an input signal or for generating an output signal, or that performs additional or supporting functions in a measurement application. A measurement application device can also be implemented as a program or software application that runs as a measurement application on a computer or processor and can communicate with other measurement application devices in order to fulfill a measurement task. A measurement application, also referred to as a measurement or test setup, can for example comprise at least one or more different measurement application devices that are used for electrical, magnetic or electromagnetic measurements, in particular on individual devices under test, also called DUT. A measurement application device according to the present disclosure can be configured to carry out such electrical, magnetic or electromagnetic measurements or signal generation, for example in a measurement laboratory or in a production facility in the respective production line, on a device under test. An exemplary measurement setup can serve to qualify the individual devices under test, i.e., to check the correct electrical function of the respective devices under test.

For this purpose, measurement application devices can comprise at least one signal acquisition part for acquiring electrical, magnetic or electromagnetic signals from the device under test and/or at least one signal generation part for generating electrical, magnetic or electromagnetic signals that can be fed to the device under test. Such a signal acquisition part can include, for example, but not limited thereto, a front-end stage for receiving, filtering, attenuating or amplifying electrical signals. The signal generation part can include, for example, but not limited thereto, corresponding signal generators, amplifiers and filters. In embodiments, signal acquisition via the signal acquisition part takes place in a wired or contact-based manner. For this purpose, a corresponding measurement probe (also called a probe) can be connected to the measurement application device via a corresponding cable. Likewise, in embodiments, signal generation and output takes place via the signal generation part in a wired or contact-based manner. For this purpose, a corresponding signal output probe can be connected to the measurement application device via a corresponding cable, or the signal is output directly via the cable, e.g., to a device under test. In further embodiments, signal acquisition can take place contactlessly, e.g., via corresponding antennas, also called OTA or over-the-air. In further embodiments, signal generation and output can take place contactlessly, e.g., via corresponding antennas, also called OTA or over-the-air. A combination of contact-based signal acquisition, contactless signal acquisition, contact-based signal generation and output, and contactless signal generation and output is also possible.

Furthermore, in signal acquisition, measurement application devices can comprise a signal processing unit that processes the acquired signals. The processing can include converting the acquired signals from analog to digital signals or vice versa and any other type of digital signal processing, for example the conversion of time domain signals into frequency domain signals.

The measurement application devices can also have a user interface in order to display the acquired signals to the user and to enable the user to control the measurement application devices. Of course, a housing can be provided that comprises the elements of the measurement application device. It is understood that additional elements such as a power supply circuit and communication interfaces can be provided.

A measurement application device can be a standalone device that can be operated without further elements in a measurement application in order to perform tests on a device under test. Of course, communication capabilities can also be provided in order to connect the measurement application device with other measurement application devices.

A measurement application device can be, for example, a signal recording device such as an oscilloscope, in particular a digital oscilloscope, a spectrum analyzer or a vector network analyzer. A measurement application device can also comprise a signal generation device, e.g., a signal generator, in particular a so-called “arbitrary signal generator”, also referred to as an “arbitrary waveform generator”, or a vector signal generator. Further possible measurement application devices include devices such as calibration standards or measurement probe tips.

Of course, at least some of the possible functions, such as signal recording and signal generation, can be combined in a single measurement application device.

In embodiments, the measurement application device can comprise pure data acquisition devices that are capable of acquiring an input signal and transmitting the acquired input signal as a digital input signal to a corresponding data memory or application server. Such pure data acquisition devices do not necessarily have a user interface or a display. Instead, such pure data acquisition devices can be remotely controlled, e.g., via a corresponding data connection such as a network interface or a USB interface. The same applies to pure signal generation devices that can generate an output signal without having a user interface or configuration input devices. Instead, such signal generation devices can be operated remotely via a data connection.

It is understood that the designation of the first outer layers and the second outer layers merely serves to distinguish between the layers and does not represent a functional limitation. In particular, components can also be mounted, for example, on the outermost of the second outer layers.

Further embodiments and developments result from the dependent claims and from the description with reference to the figures. In particular, all embodiments mentioned herein can be combined with one another in any order or number, unless individual features are mutually exclusive. In particular, the dependent claims of one claim category can also be developed according to another claim category.

In one embodiment, which can be combined with all embodiments mentioned herein, the heat dissipation element can contact one of the first outer layers on the first side. Alternatively, the heat dissipation element can contact one of the second outer layers on the second side. Further alternatively, the heat dissipation element can contact one of the first outer layers on the first side, and contact one of the second outer layers on the second side.

In such embodiments, the respective surface of the heat dissipation element is at least partially covered by the corresponding outer layer.

The direct contact with one of the outer layers enables increased heat dissipation. At the same time, if required, an electrical connection, e.g., of a ground, supply or signal line, can be provided between the heat dissipation element and a conductor track on the corresponding one of the outer layers.

It is understood that conductor tracks can be provided as required on both the first and second outer layers and the inner layers in all embodiments of the circuit carrier.

In a further embodiment, which can be combined with all embodiments mentioned herein, at least one of the first outer layers can have one or more through-connection elements which contact the outer surface of the outermost of the first outer layers with the first side of the heat dissipation element. Alternatively, at least one of the second outer layers can have one or more through-connection elements which contact the outer surface of the outermost of the second outer layers with the second side of the heat dissipation element. Further alternatively, at least one of the first outer layers can have one or more through-connection elements which contact the outer surface of the outermost of the first outer layers with the first side of the heat dissipation element, and at least one of the second outer layers can have one or more through-connection elements which contact the outer surface of the outermost of the second outer layers with the second side of the heat dissipation element.

The through-connection elements, also called vias, are usually made metallic or electrically conductive. Such through-connection elements usually have a lower thermal resistance than the material of the first or second outer layers, and thus improve the thermal contacting of the respective component with the heat dissipation element through the first outermost layers. The through-connection elements can be designed such that they form a type of channel in their interior. For example, through-connection elements can be manufactured from a bore, the inner walls of which are coated with electrically conductive material.

If through-connection elements are used in connection with the second outer layers, the heat dissipation from the heat dissipation element through the second outer layers is improved. Such through-connection elements consequently penetrate the second outer layers.

The through-connection elements can furthermore also establish an electrical contact as required.

In yet a further embodiment, which can be combined with all embodiments mentioned herein, at least one of the through-connection elements can penetrate the outermost of the first outer layers, and the heat dissipation element, and the outermost of the second layers. Such through-connection elements lead directly from the component through the entire circuit carrier and increase heat dissipation.

In yet an embodiment, which can be combined with all embodiments mentioned herein, at least one first of the through-connection elements can penetrate the outermost of the first outer layers, and the heat dissipation element. The second outer layers can have a recess above the at least one first of the through-connection elements. Alternatively, at least one second of the through-connection elements can penetrate the outermost of the second outer layers, and the heat dissipation element. The first outer layers can have a recess above the at least one second of the through-connection elements. Further alternatively, at least one first of the through-connection elements can penetrate the outermost of the first outer layers, and the heat dissipation element, and the second outer layers can have a recess above the at least one first of the through-connection elements. Additionally, at least one second of the through-connection elements can penetrate the outermost of the second outer layers, and the heat dissipation element, and the first outer layers can have a recess above the at least one second of the through-connection elements.

Particularly in combination with through-connection elements that have an inner channel, providing a recess above the respective through-connection elements can enable a gas exchange between the underside of the respective component and the opposite side of the circuit carrier.

Such a gas exchange ensures, for example, that gases released by flux during soldering of the respective component can escape. The quality of the solder connection can thereby be increased, since gas inclusions in the solder are avoided. This is particularly advantageous in the case of the above-mentioned “exposed ground pad”, which is usually located under the component and not at its edge.

In a further embodiment, which can be combined with all embodiments mentioned herein, separate gas exchange channels can be provided to enable gas exchange.

In yet a further embodiment, which can be combined with all embodiments mentioned herein, the surface of the first side of the heat dissipation element can be smaller than the surface of the second side of the heat dissipation element. Correspondingly, the cross-section or the area of the recess can increase from the first outer layers to the second outer layers.

The enlargement of the surface from the first side to the second side enables the concentrated absorption of heat, e.g., at an “exposed ground pad” of the component, and the distribution of this heat over a larger area on the second side of the heat dissipation element.

The enlargement can take place in one or more steps or stages. Such steps or stages can take place, for example, along one axis or in two axes or rotated about a vertical axis. The enlargement can thus be, for example, stepped or pyramidal. In a cross-section through the vertical axis, a corresponding heat dissipation element can correspond to an upside-down T.

In further embodiments, the enlargement can take place linearly in one or two axes. Such an enlargement can be triangular in cross-section through the vertical axis, or have a conical shape.

The heat dissipation element can be shaped corresponding to the recess.

In a plan view, the heat dissipation element can have a round, oval or angular shape.

In a further embodiment, which can be combined with all embodiments mentioned herein, the heat dissipation element can comprise or consist of at least one metal, or a metal alloy, or a ceramic material or a combination thereof.

The heat dissipation element can be made, for example, in one piece from one of the materials mentioned. In embodiments, the heat dissipation element can also have a corresponding coating on a core made of a different material. For example, a core made of ceramic material or a metal can have a coating, e.g., made of gold.

In yet a further embodiment, which can be combined with all embodiments mentioned herein, the heat dissipation element can be fastened in the internal recess by means of at least one of the following options: press-fitting, press-fitting, wherein the internal recess has a rough surface, press-fitting, wherein the surfaces of the internal recess have projections or ribs, and adhesive bonding.

Depending on the application, one of the mentioned options for fastening the heat dissipation element can be selected. Fastening without adhesive, i.e., by press-fitting with or without a rough surface or with or without ribs, can be carried out very simply and only requires a corresponding dimensioning of the respective elements. An adhesively bonded connection can possibly achieve higher strength.

In yet an embodiment, which can be combined with all embodiments mentioned herein, an electrical component can be arranged on the outermost of the first outer layers above the heat dissipation element. As already explained above, in this way the heat dissipation from the component to the heat dissipation element is ensured.

Additionally or alternatively, a cooling element can be arranged on the outermost of the second outer layers above the heat dissipation element or on the second side of the heat dissipation element. A cooling element, passive or active with a fan or liquid channels, increases heat dissipation compared to pure heat dissipation by convection from the surface of the heat dissipation element.

In one embodiment, which can be combined with all embodiments mentioned herein, a heat source can be arranged on the outermost of the second outer layers or on the second side of the heat dissipation element above the heat dissipation element. Such a heat source can be provided alternatively or in addition to a cooling element.

With the aid of a heat source, the respective component, which is arranged on the opposite side of the heat dissipation element, can be actively brought to a predetermined temperature. This can be advantageous, for example, in level detectors that require a predetermined operating temperature.

### BRIEF DESCRIPTION OF THE DRAWINGS

The present disclosure is explained in more detail below with reference to the exemplary embodiments indicated in the schematic figures of the drawings.

FIG. 1 shows a possible embodiment of a circuit carrier according to the present disclosure in cross-section;

FIG. 2 shows a further possible embodiment of a circuit carrier according to the present disclosure in cross-section;

FIG. 3 shows a further possible embodiment of a circuit carrier according to the present disclosure in cross-section;

FIG. 4 shows a further possible embodiment of a circuit carrier according to the present disclosure in cross-section;

FIG. 5 shows a further possible embodiment of a circuit carrier according to the present disclosure in cross-section;

FIG. 6 shows a flow chart of a possible embodiment of a method according to the present disclosure;

FIG. 7 shows a block diagram of an embodiment of an oscilloscope, which can be a measurement application device according to the present disclosure; and

FIG. 8 shows a block diagram of a further embodiment of an oscilloscope, which can be a measurement application device according to the present disclosure.

In all figures, functionally identical elements and devices-unless otherwise specified have been provided with similar reference signs, which are identical at least in the two least significant digits (units and tens).

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

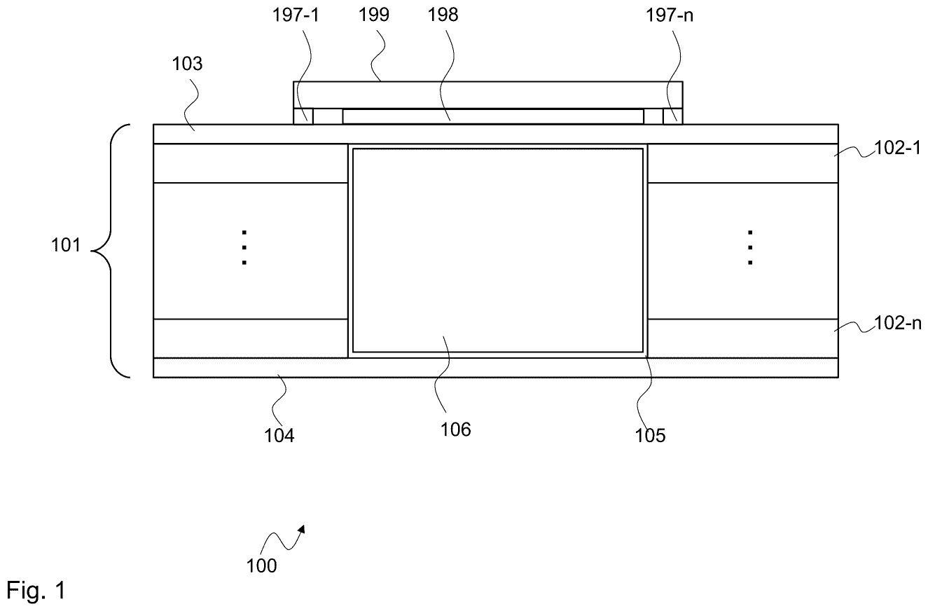

FIG. 1 shows a circuit carrier 100. The circuit carrier 100 comprises a carrier substrate 101. The carrier substrate 101 has, by way of example, a plurality of inner layers 102-1-102-n, wherein a single inner layer 102-1 is also possible. Furthermore, the carrier substrate 101 has, by way of example, a first outer layer 103 and a second outer layer 104, which are arranged on opposite sides of the inner layers 102-1-102-n. Furthermore, the circuit carrier 100 comprises an internal recess 105, which extends from the first outer layer 103 to the second outer layer 104 through the inner layers 102-1-102-n. It is understood that a plurality of first outer layers and a plurality of second outer layers are possible. Furthermore, the circuit carrier 100 comprises a heat dissipation element 106, which is arranged in the recess 105 between the first outer layer 103 and the second outer layer 104. The explanations regarding further embodiments of the circuit carrier can be applied mutatis mutandis to the circuit carrier 100.

On the top side or the outer side of the first outer layer 103, an exemplary component 199, e.g., an amplifier, is applied. The component 199 has a large-area ground contact 198, e.g., a so-called “exposed ground pad”. Furthermore, the component 199 has electrical contacts 197-1, 197-2. The ground contact 198 is arranged approximately in the middle under the component 199. The electrical contacts 197-1, 197-2 are arranged on the underside of the component 199 around the ground contact 198. It is understood that the individual electrical contacts 197-1, 197-2 and the ground contact 198 can be electrically coupled, e.g., soldered, to corresponding conductors or contacts on the top side of the first outer layer 103. In further embodiments, further components can be arranged on the circuit carrier 100, wherein a corresponding heat dissipation element 106 can be, but does not have to be, provided for some or all of them.

The heat dissipation element 106 is arranged under the first outer layer 103 directly under the ground contact 198. Heat that must be dissipated from the component 199 therefore only has to be transported through the first outer layer 103 into the heat dissipation element 106, and can then be transported from there into the second outer layer 104, where it can be released to the environment.

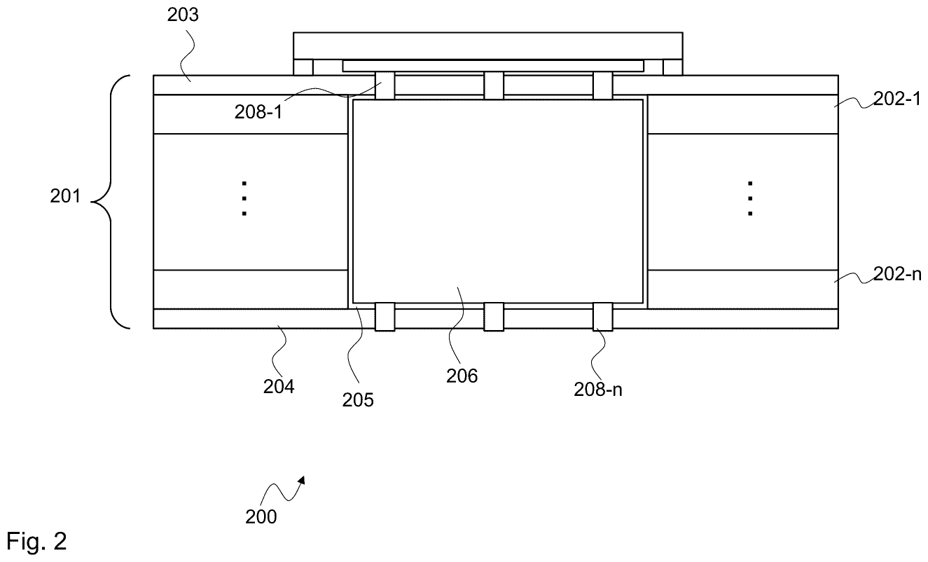

FIG. 2 shows a circuit carrier 200. The circuit carrier 200 is based on the circuit carrier 100. The circuit carrier 200 therefore comprises a carrier substrate 201. The carrier substrate 201 has, by way of example, a plurality of inner layers 202-1-202-n, wherein a single inner layer 202-1 is also possible. Furthermore, the carrier substrate 201 has, by way of example, a first outer layer 203 and a second outer layer 204, which are arranged on opposite sides of the inner layers 202-1-202-n. Furthermore, the circuit carrier 200 comprises an internal recess 205, which extends from the first outer layer 203 to the second outer layer 204 through the inner layers 202-1-202-n. It is understood that a plurality of first outer layers and a plurality of second outer layers are possible. Furthermore, the circuit carrier 200 comprises a heat dissipation element 206, which is arranged in the recess 205 between the first outer layer 203 and the second outer layer 204. The explanations regarding further embodiments of the circuit carrier can be applied mutatis mutandis to the circuit carrier 200.

The circuit carrier 200 further comprises through-connection elements 208-1-208-n. By way of example only, three of the through-connection elements 208-1-208-n are arranged in the first outer layer 203, and three of the through-connection elements 208-1-208-n are arranged in the second outer layer 204. It is understood that the number of through-connection elements can be adapted to the respective application. In embodiments, the through-connection elements 208-1-208-n can lead only through the first outer layer 203 or the second outer layer 204.

In the circuit carrier 200, the through-connection elements 208-1-208-n each lead through the first outer layer 203 or the second outer layer 204. The through-connection elements 208-1-208-n, which lead through the first outer layer 203, furthermore contact the ground contact of the component.

The through-connection elements 208-1-208-n can consist of or comprise a material which has a higher thermal conductivity than the material of the first outer layer 203 or the second outer layer 204. This improves the heat conduction to or from the heat dissipation element 206.

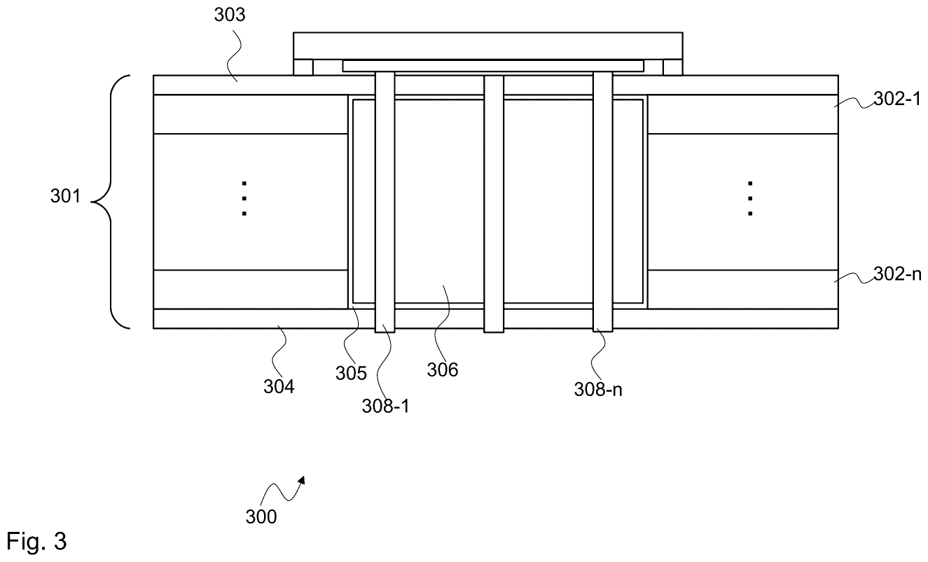

FIG. 3 shows a circuit carrier 300. The circuit carrier 300 is based on the circuit carrier 200. The circuit carrier 300 therefore comprises a carrier substrate 301. The carrier substrate 301 has, by way of example, a plurality of inner layers 302-1-302-n, wherein a single inner layer 302-1 is also possible. Furthermore, the carrier substrate 301 has, by way of example, a first outer layer 303 and a second outer layer 304, which are arranged on opposite sides of the inner layers 302-1-302-n. Furthermore, the circuit carrier 300 comprises an internal recess 305, which extends from the first outer layer 303 to the second outer layer 304 through the inner layers 302-1-302-n. It is understood that a plurality of first outer layers and a plurality of second outer layers are possible. Furthermore, the circuit carrier 300 comprises a heat dissipation element 306, which is arranged in the recess 305 between the first outer layer 303 and the second outer layer 304. The circuit carrier 300 further comprises through-connection elements 308-1-308-n. By way of example only, three of the through-connection elements 308-1-308-n are shown. The explanations regarding further embodiments of the circuit carrier can be applied mutatis mutandis to the circuit carrier 300.

In the circuit carrier 300, the individual through-connection elements 308-1-308-n lead through the entire heat dissipation element 306. Of the three through-connection elements 308-1-308-n shown by way of example, the middle through-connection element is not coupled to the ground contact of the component. Such a through-connection element can be hollow on the inside and thus serve to remove, e.g., gases that arise during soldering, from the intermediate space between the ground contact and the first outer layer 303.

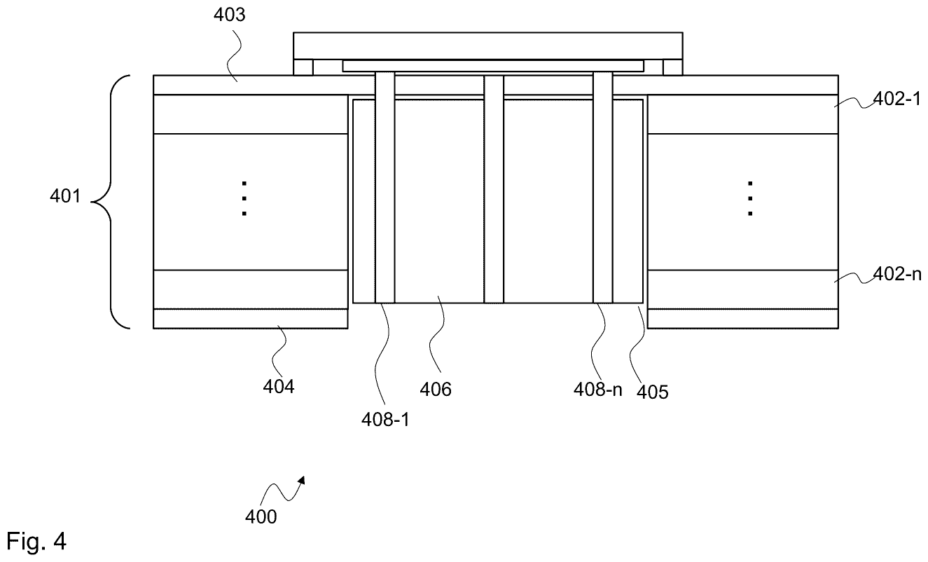

FIG. 4 shows a circuit carrier 400. The circuit carrier 400 is based on the circuit carrier 300. The circuit carrier 400 therefore comprises a carrier substrate 401. The carrier substrate 401 has, by way of example, a plurality of inner layers 402-1-402-n, wherein a single inner layer 402-1 is also possible. Furthermore, the carrier substrate 401 has, by way of example, a first outer layer 403 and a second outer layer 404, which are arranged on opposite sides of the inner layers 402-1-402-n. Furthermore, the circuit carrier 400 comprises an internal recess 405, which extends from the first outer layer 403 to the second outer layer 404 through the inner layers 402-1-402-n. It is understood that a plurality of first outer layers and a plurality of second outer layers are possible. Furthermore, the circuit carrier 400 comprises a heat dissipation element 406, which is arranged in the recess 405 between the first outer layer 403 and the second outer layer 404. The circuit carrier 400 further comprises through-connection elements 408-1-408-n. By way of example only, three of the through-connection elements 408-1-408-n are shown. The explanations regarding further embodiments of the circuit carrier can be applied mutatis mutandis to the circuit carrier 400.

In the circuit carrier 400, the three through-connection elements 408-1-408-n shown likewise extend through the first outer layer 403 and the heat dissipation element 406.

The second outer layer 404 has a recess in the region of the heat dissipation element 406, so that the surface of the heat dissipation element 406 is exposed. This enables improved heat dissipation from the heat dissipation element 406.

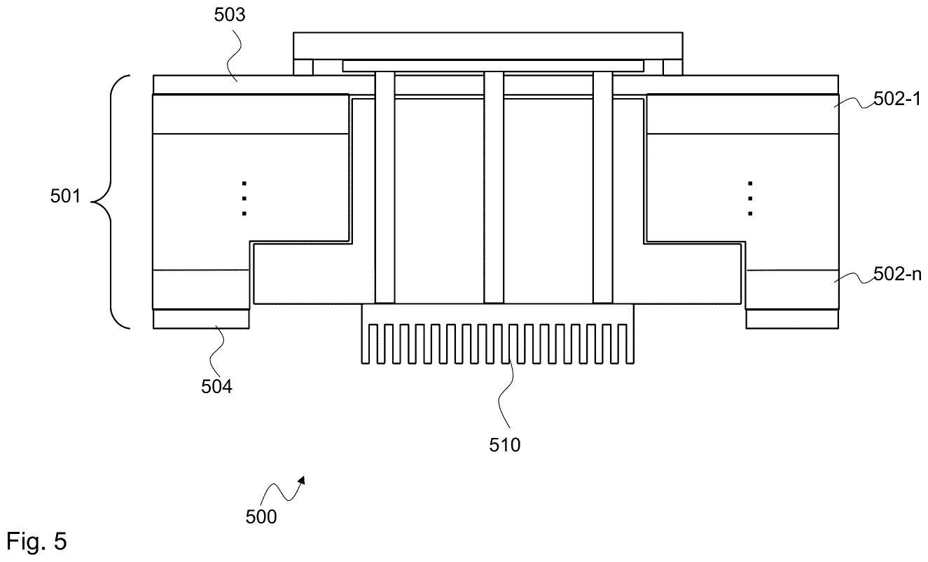

FIG. 5 shows a circuit carrier 500. The circuit carrier 500 is based on the circuit carrier 400. The circuit carrier 500 therefore comprises a carrier substrate 501. The carrier substrate 501 has, by way of example, a plurality of inner layers 502-1-502-n, wherein a single inner layer 502-1 is also possible. Furthermore, the carrier substrate 501 has, by way of example, a first outer layer 503 and a second outer layer 504, which are arranged on opposite sides of the inner layers 502-1-502-n. Furthermore, the circuit carrier 500 comprises an internal recess 505, which extends from the first outer layer 503 to the second outer layer 504 through the inner layers 502-1-502-n. It is understood that a plurality of first outer layers and a plurality of second outer layers are possible. Furthermore, the circuit carrier 500 comprises a heat dissipation element 506, which is arranged in the recess 505 between the first outer layer 503 and the second outer layer 504. The circuit carrier 500 further comprises through-connection elements 508-1-508-n. By way of example only, three of the through-connection elements 508-1-508-n are shown. The second outer layer 504 has a recess in the region of the heat dissipation element 506, so that the surface of the heat dissipation element 506 is exposed. The explanations regarding further embodiments of the circuit carrier can be applied mutatis mutandis to the circuit carrier 500.

In the cross-section shown, the heat dissipation element 506 has the shape of an upside-down T. The region of the heat dissipation element 506 which lies on the first outer layer 503 is narrower than the region which lies on the second outer layer 504. The recess 505 is shaped accordingly. Other shapes for the heat dissipation element 506 are also possible, as already explained above.

Furthermore, a cooling element 510 is shown by way of example on the exposed surface of the heat dissipation element 506. In embodiments, the cooling element 510 can be replaced or supplemented by a heat source.

In embodiments, the circuit carriers 300, circuit carriers 400 and circuit carriers 500 can also be implemented without through-connection elements or with the through-connection elements shown for the circuit carrier 200. The circuit carrier 200 can be implemented with the through-connection elements shown for the circuit carriers 300, circuit carriers 400 and circuit carriers 500.

For the sake of clarity, the reference characters from the device-related figures are retained for the description of the method.

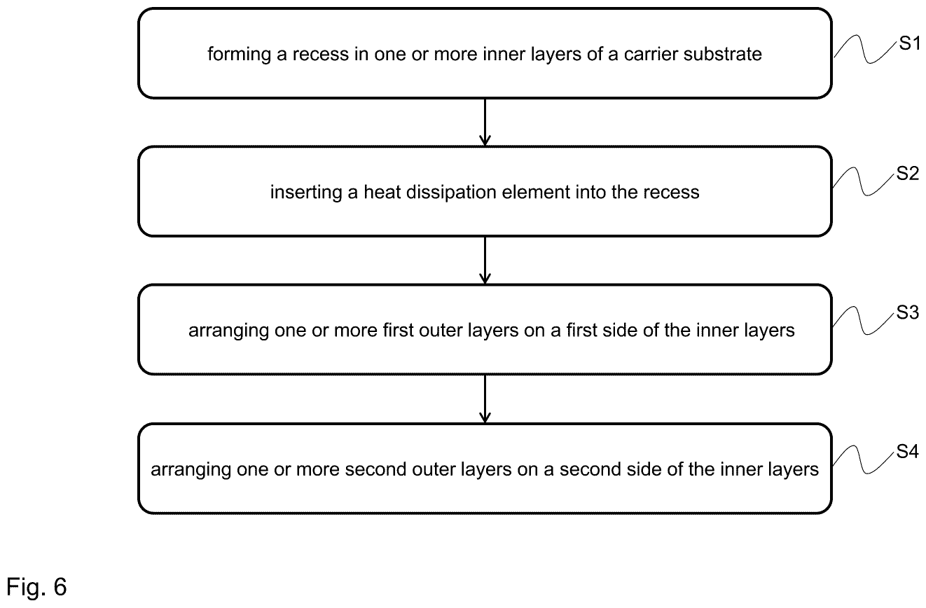

FIG. 6 shows a flow chart of a method for producing a circuit carrier 100, 200, 300, 400, 500.

The method comprises: forming a recess 105, 205, 305, 405, 505 in one or more inner layers 102-1-102-n, 202-1-202-n, 302-1-302-n, 402-1-402-n, 502-1-502-n of a carrier substrate 101, 201, 301, 401, 501, inserting a heat dissipation element 106, 206, 306, 406, 506 into the recess 105, 205, 305, 405, 505, arranging one or more first outer layers 103, 203, 303, 403, 503 on a first side of the inner layers 102-1-102-n, 202-1-202-n, 302-1-302-n, 402-1-402-n, 502-1-502-n, and arranging one or more second outer layers 104, 204, 304, 404, 504 on a second side of the inner layers 102-1-102-n, 202-1-202-n, 302-1-302-n, 402-1-402-n, 502-1-502-n. The heat dissipation element 106, 206, 306, 406, 506 has a first side facing the first outer layers 103, 203, 303, 403, 503, and a second side facing the second outer layers 104, 204, 304, 404, 504.

In embodiments, the method can further comprise arranging one or more through-connection elements 208-1-208-n, 308-1-308-n, 408-1-408-n in at least one of the first outer layers 103, 203, 303, 403, 503, wherein the through-connection elements 208-1-208-n, 308-1-308-n, 408-1-408-n contact the outer surface of the outermost of the first outer layers 103, 203, 303, 403, 503 with the first side of the heat dissipation element 106, 206, 306, 406, 506. The method can also comprise arranging one or more through-connection elements 208-1-208-n, 308-1-308-n, 408-1-408-n in at least one of the second outer layers 104, 204, 304, 404, 504, wherein the through-connection elements 208-1-208-n, 308-1-308-n, 408-1-408-n contact the outer surface of the outermost of the second layers 104, 204, 304, 404, 504 with the second side of the heat dissipation element 106, 206, 306, 406, 506. The method can also comprise attaching one or more through-connection elements 208-1-208-n, 308-1-308-n, 408-1-408-n in at least one of the first outer layers 103, 203, 303, 403, 503, wherein the through-connection elements 208-1-208-n, 308-1-308-n, 408-1-408-n contact the outer surface of the outermost of the first outer layers 103, 203, 303, 403, 503 with the first side of the heat dissipation element 106, 206, 306, 406, 506. The method further comprises attaching one or more through-connection elements 208-1-208-n, 308-1-308-n, 408-1-408-n in at least one of the second outer layers 104, 204, 304, 404, 504, wherein the through-connection elements 208-1-208-n, 308-1-308-n, 408-1-408-n contact the outer surface of the outermost of the second layers 104, 204, 304, 404, 504 with the second side of the heat dissipation element 106, 206, 306, 406, 506.

At least one of the through-connection elements 208-1-208-n, 308-1-308-n, 408-1 408-n can be designed such that it penetrates the outermost of the first outer layers 103, 203, 303, 403, 503, and the heat dissipation element 106, 206, 306, 406, 506, and the outermost of the second layers 104, 204, 304, 404, 504.

At least one first of the through-connection elements 208-1-208-n, 308-1-308-n, 408-1-408-n can further be designed such that it penetrates the outermost of the first outer layers 103, 203, 303, 403, 503, and the heat dissipation element 106, 206, 306, 406, 506, wherein a recess 105, 205, 305, 405, 505 can be arranged in the second outer layers 104, 204, 304, 404, 504 above the at least one first of the through-connection elements 208-1-208-n, 308-1-308-n, 408-1-408-n. At least one second of the through-connection elements 208-1-208-n, 308-1-308-n, 408-1-408-n can be designed such that it penetrates the outermost of the second outer layers 104, 204, 304, 404, 504, and the heat dissipation element 106, 206, 306, 406, 506, wherein a recess 105, 205, 305, 405, 505 can be arranged in the first outer layers 103, 203, 303, 403, 503 above the at least one second of the through-connection elements 208-1-208-n, 308-1-308-n, 408-1-408-n.

The method can comprise at least partially galvanizing the surface of the inner layers 102-1-102-n, 202-1-202-n, 302-1-302-n, 402-1-402-n, 502-1-502-n facing the first outer layers 103, 203, 303, 403, 503. The method can also comprise at least partially galvanizing the surface of the inner layers 102-1-102-n, 202-1-202-n, 302-1-302-n, 402-1-402-n, 502-1-502-n facing the second outer layers 104, 204, 304, 404, 504.

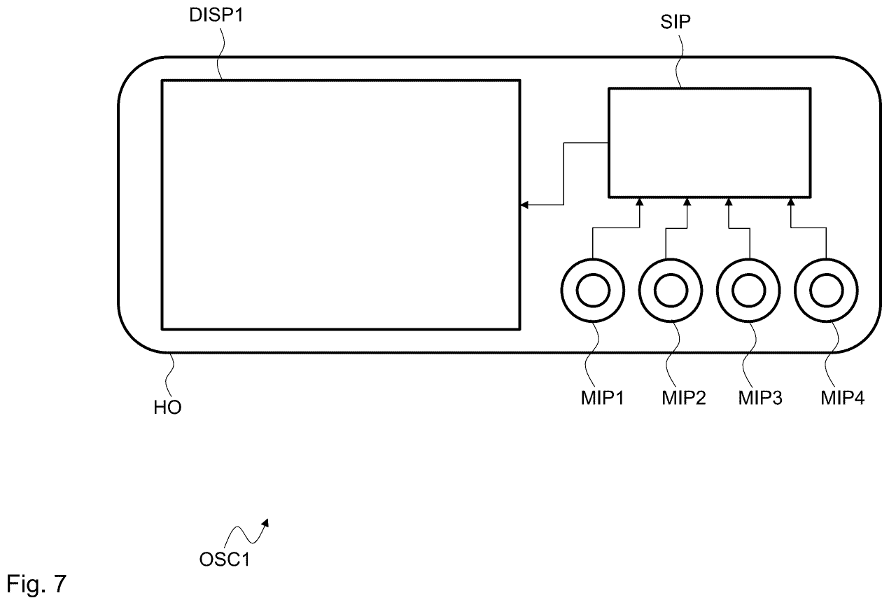

FIG. 7 shows a block diagram of an embodiment of an oscilloscope, which can be a measurement application device according to the present disclosure.

The oscilloscope OSC1 comprises a housing HO, which accommodates four measurement inputs MIP1, MIP2, MIP3, MIP4, which are connected to a signal processor SIP in order to process measured signals. The signal processor SIP is connected to a display DISP1 in order to display the measured signals to a user.

Although not explicitly shown, it is understood that the oscilloscope OSC1 can also comprise signal outputs. Such signal outputs can serve, for example, for outputting calibration signals. Such calibration signals allow the calibration of the measurement setup before carrying out measurements. The process of calibration and correction of measurement signals based on the calibration can also be referred to as “de-embedding” and can comprise applying corresponding algorithms to the generated or measured signals.

In the oscilloscope OSC1, at least one of the measurement inputs MIP1, MIP2, MIP3, MIP4 can comprise a circuit carrier 100, 200, 300, 400, 500, which can have, for example, an amplifier as a component. In further embodiments, the circuit carrier 100, 200, 300, 400, 500 can also be assigned to another element in the oscilloscope OSC1 or be arranged as an independent element in the oscilloscope OSC1.

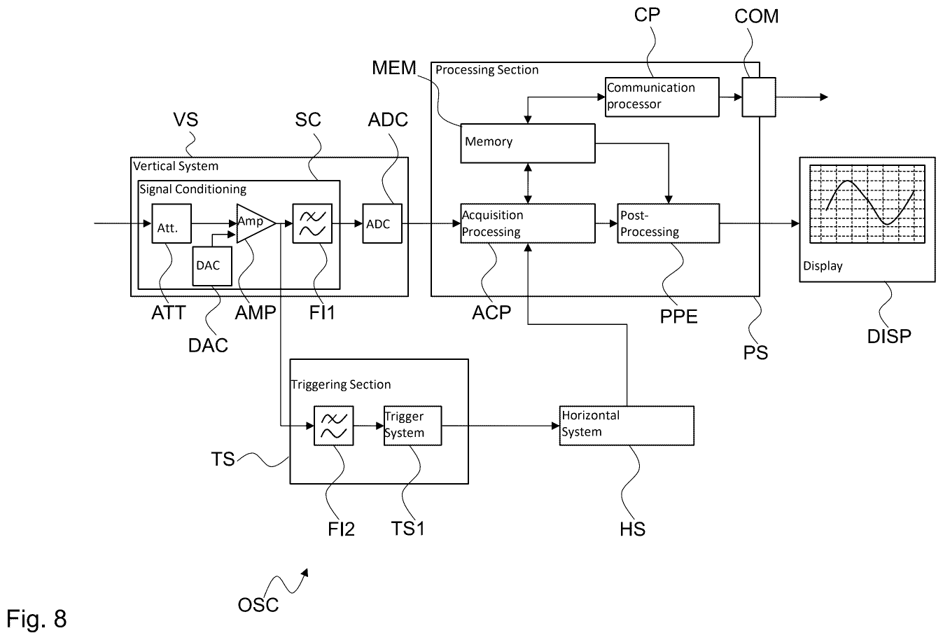

FIG. 8 shows a block diagram of an oscilloscope OSC, which can be an implementation of a measurement application device according to the present disclosure. The oscilloscope OSC is implemented as a digital oscilloscope. However, it is noted that the present disclosure can also be implemented with any other type of oscilloscope.

The oscilloscope OSC comprises, by way of example, five general sections: the vertical system VS, the triggering section TS, the horizontal system HS, the processing section PS and the display DISP. It is understood that the division into five general sections represents a logical division and in no way restricts the placement and implementation of the elements of the oscilloscope OSC.

The vertical system VS serves primarily to shift (offset), attenuate and amplify a signal to be acquired. The signal can be modified, for example, so that it fits into the available display area of the display DISP or has a vertical size configured by a user.

For this purpose, the vertical system VS comprises a signal conditioning section SC with an attenuator ATT and a digital-to-analog converter DAC, which are connected to an amplifier AMP. The amplifier AMP is connected to a filter FI1, which in the example shown is provided as a low-pass filter. The vertical system VS also comprises an analog-to-digital converter ADC, which receives the output of the filter FI1 and converts the received analog signal into a digital signal.

The attenuator ATT and the amplifier AMP serve to adapt the amplitude of the signal to be acquired to the operating range of the analog-to-digital converter ADC. The digital-to-analog converter DAC serves to modify the direct current component of the input signal to be acquired so that it fits into the operating range of the analog-to-digital converter ADC. The filter FI1 serves to filter out unwanted high-frequency components of the signal to be acquired.

The triggering section TS operates with the signal provided by the amplifier AMP. The triggering section TS comprises a filter FI2, which in this embodiment is implemented as a low-pass filter. The filter FI2 is connected to a trigger system TS1.

The triggering section TS serves to detect predefined signal events and enables the horizontal system HS, for example, to display a stable view of a repeated waveform or simply to display waveform sections that contain the respective signal event. It is understood that the predefined signal event can be configured by a user via a user input of the oscilloscope OSC.

Possible predefined signal events can include, for example, but are not limited to, when the signal exceeds a predefined trigger threshold in a predefined direction, i.e., with a rising or falling edge. Such a trigger condition is also referred to as an edge trigger. Another trigger condition is referred to as “glitch triggering” and triggers when a pulse occurs in the signal to be acquired whose width is greater or less than a predefined time.

In order to enable an exact match of the trigger signal with the waveform displayed on the display DISP, a common time base can be provided for the analog-to-digital converter ADC and the trigger system TS1.

It is understood that, although not explicitly shown, the trigger system TS1 can comprise at least one of the following components: configurable voltage comparators for setting the trigger thresholds, fixed voltage sources for setting the required edge, corresponding logic gates such as an XOR gate and flip-flops for generating the trigger signal.

The triggering section TS is provided by way of example as an analog triggering section. It is understood that the oscilloscope OSC can also be equipped with a digital triggering section. Such a digital triggering section does not operate with the analog signal provided by the amplifier AMP, but with the digital signal provided by the analog-to-digital converter ADC.

A digital triggering section can comprise a processing element, such as a processor, a DSP, a CPLD, an ASIC or an FPGA, in order to implement digital algorithms for detecting a valid trigger signal.

The horizontal system HS is connected to the output of the trigger system TS1 and serves primarily to position and scale the signal to be acquired horizontally on the display DISP.

The oscilloscope OSC further comprises a processing section PS, which implements digital signal processing and data storage for the oscilloscope. The processing section PS comprises an acquisition processing element ACP, which is connected to the output of the analog-to-digital converter ADC and the output of the horizontal system HS as well as to a memory MEM and a post processing element PPE.

The acquisition processing element ACP manages the acquisition of digital data from the analog-to-digital converter ADC and the storage of the data in the memory MEM. The acquisition processing element ACP can, for example, comprise a processing element which has a digital interface to the analog-to-digital converter ADC and a digital interface to the memory MEM. The processing element can, for example, comprise a microcontroller, a DSP, a CPLD, an ASIC or an FPGA with corresponding interfaces. In a microcontroller or DSP, the functionality of the acquisition processing element ACP can be implemented as computer-readable instructions executed by a CPU. In a CPLD or FPGA, the functionality of the acquisition processing element ACP can be configured in the CPLD or FPGA, rather than executing software from a processor.

The processing section PS further comprises a communication processor CP and a communication interface COM.

The communication processor CP can be a device that manages data transfer to and from the oscilloscope OSC. The communication interface COM can be designed for any suitable communication standard, such as Ethernet, WIFI, Bluetooth, NFC, an infrared communication standard and a visible light-based communication standard.

The communication processor CP is connected to the memory MEM and can use the memory MEM to store and retrieve data.

Of course, the communication processor CP can also be connected to any other element of the oscilloscope OSC in order to retrieve device data or provide device data received, for example, from a management server.

The post processing element PPE can be controlled by the acquisition processing element ACP and can access the memory MEM to retrieve data to be displayed on the display DISP. The post processing element PPE can process the data stored in the memory MEM so that the display DISP can display the data to a user, for example as a waveform. The post processing element PPE can also realize analysis functions such as cursors, waveform measurements, histograms or mathematical functions.

The display DISP controls all aspects of signal representation for a user and, although not explicitly shown, can comprise any component required to receive data to be displayed and to control a display device for displaying the data as desired.

It is understood that the oscilloscope OSC, even if not shown, can comprise a user interface via which a user can interact with the oscilloscope OSC. Such a user interface can comprise dedicated input elements such as buttons and switches. At least partially, the user interface can also be provided as a touch-sensitive display device.

In the oscilloscope OSC, for example, the amplifier AMP shown in the vertical system VS can be arranged on a circuit carrier 100, 200, 300, 400, 500 according to the present disclosure. Furthermore, any other component or further components not shown of the oscilloscope OSC can be arranged on a circuit carrier 100, 200, 300, 400, 500.

It is understood that all elements of the oscilloscope OSC that perform digital data processing can be provided as dedicated elements. Alternatively, at least some of the functions described above can be implemented in a single hardware element, such as a microcontroller, DSP, CPLD or FPGA. In general, the logical functions described above can be implemented in any suitable hardware element of the oscilloscope OSC and do not necessarily have to be divided into the various sections described above.

The processes, methods or algorithms disclosed herein may be conveyed to or implemented by a computing unit, controller or computer. These may comprise any existing programmable electronic control unit or dedicated electronic control unit. Likewise, the processes, methods or algorithms may be stored as data and instructions that can be executed by a controller or computer in many forms, including, but not limited to, information permanently stored on non-writable storage media such as ROM devices, and information alterably stored on writable storage media such as floppy disks, magnetic tapes, CDs, RAM devices, and other magnetic and optical media. The processes, methods or algorithms may also be implemented in a software-executable object. Alternatively, the processes, methods or algorithms may be embodied in whole or in part in suitable hardware components such as application-specific integrated circuits (ASICs), field-programmable gate arrays (FPGAs), state machines, controllers or other hardware components or devices, or a combination of hardware, software and firmware components.

Although exemplary embodiments are described above, it is understood that these embodiments do not encompass all possible forms of implementation of the present disclosure that are covered by the claims. The terms used in the specification are for the purpose of description and not limitation, and it is understood that various changes can be made without departing from the spirit and scope of the disclosure. As previously described, the features of various embodiments can be combined to form further embodiments of the invention that may not be explicitly described or illustrated. While various embodiments may be described as advantageous or preferred over other embodiments or prior art implementations with respect to one or more desired characteristics, those skilled in the art recognize that one or more characteristics or features may be compromised in favor of desired overall system characteristics, which depend on the specific application and implementation. These characteristics may include, but need not be limited to, cost, strength, durability, life cycle cost, marketability, appearance, packaging, size, serviceability, weight, manufacturability, ease of assembly, etc. Thus, to the extent that embodiments have been described as less desirable than other embodiments or prior art implementations with respect to certain characteristics, these embodiments are nevertheless within the scope of the disclosure and may be desirable for particular applications.

With respect to the processes, systems, methods, heuristics, etc. described herein, it is understood that, although the steps of such processes, etc. have been described in a particular order, such processes may also be performed in an order different from that described herein. Likewise, it is understood that certain steps may be performed concurrently, that other steps may be added, or that certain steps described herein may be omitted. In other words, the descriptions of the processes herein are for the purpose of illustrating certain embodiments and should in no way be construed as limiting the claims.

In summary, it is understood that the disclosed subject matter can be modified and varied without departing from the scope of the present disclosure.

All terms used in the claims are intended to obtain their broadest reasonable interpretations and their ordinary meanings as understood by those skilled in the technologies described herein, unless expressly indicated otherwise. In particular, the use of singular articles, such as “a,” “an,” “the,” “said,” etc., should be read to encompass one or more of the indicated elements, unless a claim expressly recites the contrary.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100, 200, 300, 400, 500 circuit carrier
101, 201, 301, 401, 501 carrier substrate
102-1-102-n, 202-1-202-n inner layer
302-1-302-n, 402-1-402-n inner layer
502-1-502-n inner layer
103, 203, 303, 403, 503 first outer layer
104, 204, 304, 404, 504 second outer layer
105, 205, 305, 405, 505 recess
106, 206, 306, 406, 506 heat dissipation element
208-1-208-n, 308-1-308-n through-connection element
408-1-408-n through-connection element
510 cooling element
199 component
198 ground contact
197-1-197-n contact
OSC1 oscilloscope
HO housing
MIP1, MIP2, MIP3, MIP4 measurement input
SIP signal processor
DISP1 display
OSC oscilloscope
VS vertical system
SC signal conditioning section
ATT attenuator
DAC digital-to-analog converter
AMP amplifier
FI1 filter
ADC analog-to-digital converter
TS triggering section
AMP2 amplifier
FI2 filter
TS1 trigger system
HS horizontal system
PS processing section
ACP acquisition processing element
MEM memory
PPE post processing element
DISP display
S1-S4 method steps

What is claimed is:

1. A circuit carrier, comprising:
a carrier substrate comprising:
one or more inner layers,
one or more first outer layers and one or more second outer layers, wherein the first outer layers and the second outer layers are arranged on opposite sides of the inner layers; and
an internal recess, which extends from at least one of the first outer layers to at least one of the second outer layers through the inner layers;
wherein the circuit carrier further comprises a heat dissipation element, which is arranged in the recess and has a first side facing the first outer layers, and a second side facing the second outer layers.

2. The circuit carrier according to claim 1, wherein the heat dissipation element contacts one of the first outer layers on the first side; or
wherein the heat dissipation element contacts one of the second outer layers on the second side; or
wherein the heat dissipation element contacts one of the first outer layers on the first side, and contacts one of the second outer layers on the second side.

3. The circuit carrier according to claim 1, wherein at least one of the first outer layers has one or more through-connection elements which contact the outer surface of the outermost of the first outer layers with the first side of the heat dissipation element; or
wherein at least one of the second outer layers has one or more through-connection elements which contact the outer surface of the outermost of the second outer layers with the second side of the heat dissipation element; or
wherein at least one of the first outer layers has one or more through-connection elements which contact the outer surface of the outermost of the first outer layers with the first side of the heat dissipation element, and wherein at least one of the second outer layers has one or more through-connection elements which contact the outer surface of the outermost of the second outer layers with the second side of the heat dissipation element.

4. The circuit carrier according to claim 3, wherein at least one of the through-connection elements penetrates the outermost of the first outer layers, and the heat dissipation element, and the outermost of the second layers.

5. The circuit carrier according to claim 3, wherein at least one first of the through-connection elements penetrates the outermost of the first outer layers, and the heat dissipation element, and wherein the second outer layers have a recess above the at least one first of the through-connection elements; or
wherein at least one second of the through-connection elements penetrates the outermost of the second outer layers, and the heat dissipation element, and wherein the first outer layers have a recess above the at least one second of the through-connection elements; or
wherein at least one first of the through-connection elements penetrates the outermost of the first outer layers, and the heat dissipation element, and wherein the second outer layers have a recess above the at least one first of the through-connection elements, and wherein at least one second of the through-connection elements penetrates the outermost of the second outer layers, and the heat dissipation element, and wherein the first outer layers have a recess above the at least one second of the through-connection elements.

6. The circuit carrier according to claim 1, wherein the surface of the first side of the heat dissipation element is smaller than the surface of the second side of the heat dissipation element.

7. The circuit carrier according to claim 1, wherein the heat dissipation element comprises at least one metal, or a metal alloy, or a ceramic material or a combination thereof; or
wherein the heat dissipation element consists at least of a metal, or a metal alloy, or a ceramic material or a combination thereof.

8. The circuit carrier according to claim 1, wherein the heat dissipation element is fastened in the internal recess by means of at least one of the following options:
press-fitting;
press-fitting, wherein the internal recess has a rough surface;
press-fitting, wherein the surfaces of the internal recess have projections or ribs; and
adhesive bonding.

9. The circuit carrier according to claim 1, wherein an electrical component is arranged on the outermost of the first outer layers above the heat dissipation element; or
wherein a cooling element is arranged on the outermost of the second outer layers above the heat dissipation element or on the second side of the heat dissipation element; or
wherein an electrical component is arranged on the outermost of the first outer layers above the heat dissipation element, and wherein a cooling element is arranged on the outermost of the second outer layers above the heat dissipation element or on the second side of the heat dissipation element.

10. The circuit carrier according to claim 1, wherein a heat source is arranged on the outermost of the second outer layers or on the second side of the heat dissipation element above the heat dissipation element.

11. A measurement application device, comprising:
at least one circuit carrier according to claim 1;
wherein, on the at least one circuit carrier, at least one electrical component is arranged on the outermost of the first outer layers above the heat dissipation element.

12. A method for producing a circuit carrier, wherein the method comprises:
forming a recess in one or more inner layers of a carrier substrate;
inserting a heat dissipation element into the recess;
arranging one or more first outer layers on a first side of the inner layers; and
arranging one or more second outer layers on a second side of the inner layers;
wherein the heat dissipation element has a first side facing the first outer layers, and a second side facing the second outer layers.

13. A method according to claim 12, further comprising:
attaching one or more through-connection elements in at least one of the first outer layers, wherein the through-connection elements contact the outer surface of the outermost of the first outer layers with the first side of the heat dissipation element; or
arranging one or more through-connection elements in at least one of the second outer layers, wherein the through-connection elements contact the outer surface of the outermost of the second layers with the second side of the heat dissipation element; or
arranging one or more through-connection elements in at least one of the first outer layers, wherein the through-connection elements contact the outer surface of the outermost of the first outer layers with the first side of the heat dissipation element, and attaching one or more through-connection elements in at least one of the second outer layers, wherein the through-connection elements contact the outer surface of the outermost of the second layers with the second side of the heat dissipation element.

14. A method according to claim 13, wherein at least one of the through-connection elements is designed such that it penetrates the outermost of the first outer, and the heat dissipation element, and the outermost of the second layers.

15. A method according to claim 13, wherein at least one first of the through-connection elements is designed such that it penetrates the outermost of the first outer layers, and the heat dissipation element, and wherein a recess is arranged in the second outer above the at least one first of the through-connection elements; or
wherein at least one second of the through-connection elements is designed such that it penetrates the outermost of the second outer layers, and the heat dissipation element, and wherein a recess is arranged in the first outer layers above the at least one second of the through-connection elements; or
wherein at least one first of the through-connection elements is designed such that it penetrates the outermost of the first outer layers, and the heat dissipation element, and wherein a recess is arranged in the second outer layers above the at least one first of the through-connection elements, and wherein at least one second of the through-connection elements is designed such that it penetrates the outermost of the second outer layers, and the heat dissipation element, and wherein a recess is arranged in the first outer layers above the at least one second of the through-connection elements.

16. A method according to claim 12, further comprising:
at least partially galvanizing the surface of the inner layers facing the first outer layers; or
at least partially galvanizing the surface of the inner layers facing the second outer layers; or
at least partially galvanizing the surface of the inner layers facing the first outer layers, and at least partially galvanizing the surface of the inner layers facing the second outer layers.
